(19) United States
(12) Patent Application Publication
(10) Pub. No.: US 2024/0118167 A1
(43) Pub. Date: Apr. 11, 2024

(54) Circuit, Device and Method for Optical Characteristic Inspection

(71) Applicant: Nippon Telegraph and Telephone Corporation, Tokyo (JP)

(72) Inventors: Yoshiho Maeda, Musashino-shi, Tokyo (JP); Toru Miura, Musashino-shi, Tokyo (JP); Hiroshi Fukuda, Musashino-shi, Tokyo (JP)

(21) Appl. No.: 18/546,161

(22) PCT Filed: Mar. 25, 2021
(86) PCT No.: PCT/JP2021/012522

§ 371 Date: Aug. 11, 2023

(51) Int. Cl. G01M 11/00; G01M 11/02; G01R 19/00

(52) U.S. Cl. CPC G01M 11/338; G01M 11/02; G01M 11/331; G01R 19/0061; G02B 6/4201

(57) ABSTRACT

An optical characteristic inspection circuit includes, in order, an optical input element, an optical splitter circuit including a resistor, a first optical circuit to be inspected connected to one output of the optical splitter circuit, a second optical circuit to be inspected connected to another output of the optical splitter circuit, and a photodetector that detects an intensity of light transmitted through the first optical circuit to be inspected and an intensity of light transmitted through the second optical circuit to be inspected. Therefore, the present invention can provide an optical characteristic inspection circuit capable of reducing man-hours required for optical characteristic inspection.

### TECHNICAL FIELD

The present invention relates to an optical characteristic inspection circuit, device, and method for inspecting an optical waveguide.

### BACKGROUND ART

Inspection of an optical circuit requires time for alignment of an optical fiber with respect to the optical circuit in order to input light to the optical circuit to be inspected and obtain optical output. For example, in a case where a normal single mode fiber is used, it is necessary to adjust a position of the optical fiber with a spatial resolution of 1 μm or less. Therefore, it is difficult to reduce man-hours.

In order to reduce man-hours required for the inspection, it is effective to omit at least either optical input or optical output. It is difficult to omit the optical input, but it is possible to use electrical output from a photodetector directly connected to the optical circuit, instead of the optical output. Electrical input and output only require an electrical contact, and the alignment generally only needs to be performed with the spatial resolution of 10 μm or more. Therefore, it does not take time for the alignment, and inspection man-hours can be significantly reduced by using the electrical input and output.

However, each photodetector to be directly connected to the optical circuit generally has variations in characteristics. In particular, individual germanium photodiodes used in silicon photonics have large variations in sensitivity, and thus it is necessary to individually correct the sensitivity of each germanium photodiode in order to inspect the characteristic of the optical circuit on the basis of a photocurrent absolute value thereof.

For example, as illustrated in FIG. 5, in an optical characteristic inspection circuit 30, a wafer surface optical input element 31_1 such as a grating coupler and a photodetector 34_1 are provided in an optical circuit 33_1 formed on a substrate, and a wafer surface optical input element 31_2 and a photodetector 34_2 are provided in an optical circuit 33_2. In the optical characteristic inspection circuit 30, a difference between electrical output of the photodetector 34_1 and electrical output of the photodetector 34_2 is measured to evaluate waveguide loss of the optical circuits 33_1 and 33_2. However, in a case where the photodetectors have variations in characteristics as described above, the waveguide loss cannot be accurately evaluated.

In a case where the individual wafer surface optical input elements 31_1 and 31_2 have variations in characteristics, those characteristic variations are also superimposed on the evaluation results based on the electrical output of the photodetectors 34_1 and 34_2, and thus the waveguide loss cannot be accurately evaluated.

In order to reduce the inspection man-hours of the optical circuit, an optical characteristic inspection circuit 40 is disclosed as illustrated in FIG. 6 (Patent Literature 1). The optical characteristic inspection circuit 40 includes a wafer surface optical input element 41 and a photodetector 44 common to two optical circuits 43_1 and 43_2 formed on a substrate. By sweeping a wavelength of light input to the optical characteristic inspection circuit 40 and evaluating the waveguide loss, it is possible to avoid an influence of variations in characteristics of individual wafer surface optical input elements and photodetectors.

### CITATION LIST

### Patent Literature

Patent Literature 1: JP 2019-96763 A

### Non Patent Literature

Non Patent Literature 1: Jens Bolten, Jens Hofrichter, Nikolaj Moll, Sophie Schonenberger, Folkert Horst, Bert J. Offrein, Thorsten Wahlbrink, Thomas Mollenhauer, Heinrich Kurz, “CMOS compatible cost-efficient fabrication of SOI grating couplers,” Microelectronic Engineering, Volume 86,Issues 4-6, 2009, Pages 1114-1116, ISSN 0167-9317, https://doi.org/10.1016/j.mee.2008.11.038.

### SUMMARY OF INVENTION

### Technical Problem

However, a grating coupler (GC) used as an optical input port in the optical characteristic inspection circuit 40 has steep wavelength dependence (Non Patent Literature 1). As a result, as disclosed in Patent Literature 1, in a method of sweeping a wavelength of input light, a wavelength characteristic of a GC serving as an input port is superimposed on a waveform output from a waveguide that is a device under test (DUT). Therefore, an optical characteristic (waveguide loss) of the waveguide cannot be accurately evaluated.

As described above, it is difficult to accurately evaluate the optical characteristic (waveguide loss) of the waveguide by directly applying the optical characteristic inspection circuit 40 to on-wafer optical characteristic inspection.

### Solution to Problem

In order to solve the above problems, an optical characteristic inspection circuit according to the present invention includes, in order, an optical input element, an optical splitter circuit including a resistor, a first optical circuit to be inspected connected to one output of the optical splitter circuit, a second optical circuit to be inspected connected to another output of the optical splitter circuit, and a photodetector configured to detect an intensity of light transmitted through the first optical circuit to be inspected and an intensity of light transmitted through the second optical circuit to be inspected.

### Advantageous Effects of Invention

According to the present invention, it is possible to provide an optical characteristic inspection circuit, device, and method capable of reducing man-hours required for optical characteristic inspection.

### BRIEF DESCRIPTION OF DRAWINGS

FIG. 1 is a block diagram illustrating a configuration of an optical characteristic inspection device according to a first embodiment of the present invention.

FIG. 2 is a schematic diagram illustrating a configuration example of an optical characteristic inspection circuit according to a first example of the present invention.

FIG. 3 illustrates an example of output of the optical characteristic inspection circuit according to the first example of the present invention.

FIG. 4 is a schematic diagram illustrating a configuration example of an optical characteristic inspection circuit according to a second example of the present invention.

FIG. 5 is a schematic diagram illustrating a configuration example of a conventional optical characteristic inspection circuit.

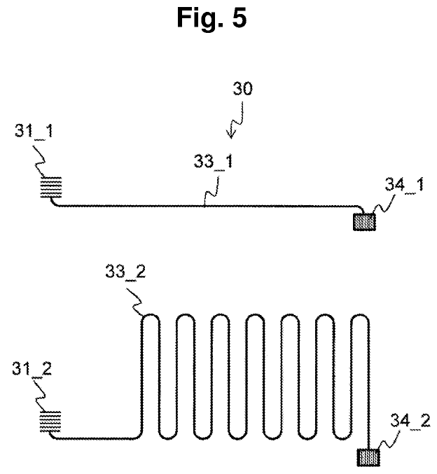

FIG. 6 is a schematic diagram illustrating a configuration example of a conventional optical characteristic inspection circuit.

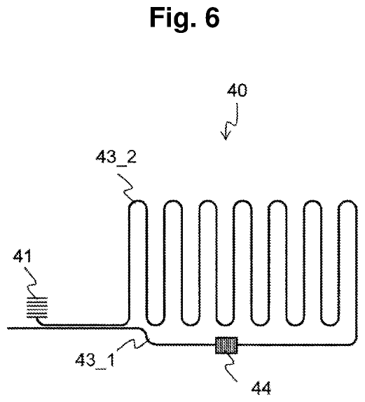

### DESCRIPTION OF EMBODIMENTS

### First Embodiment

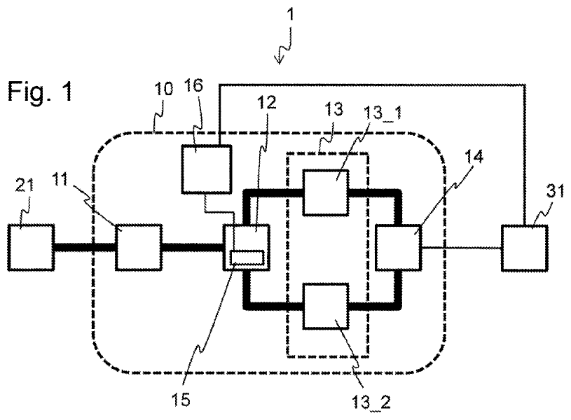

An optical characteristic inspection circuit and an optical characteristic inspection device according to a first embodiment of the present invention will be described with reference to FIG. 1.

Configurations of Optical Characteristic Inspection Circuit and Optical Characteristic Inspection Device

As illustrated in FIG. 1, an optical characteristic inspection device 1 according to the present embodiment includes an optical characteristic inspection circuit 10, an optical fiber 21, and a control unit 31.

The optical characteristic inspection circuit 10 is an on-wafer optical characteristic inspection circuit fabricated on the same wafer and includes an optical input element 11, an optical splitter circuit 12, a first optical circuit to be inspected (hereinafter, referred to as “first optical circuit”) 13_1, a second optical circuit to be inspected (hereinafter, referred to as “second optical circuit”) 13_2, and a photodetector 14.

In the optical characteristic inspection circuit 10, a resistor 15 is disposed in a waveguide of the optical splitter circuit 12. Further, an electrode 16 is disposed in the resistor 15 via electric wiring.

The control unit 31 is electrically connected to both the photodetector 14 and the electrode 16. The control unit 31 includes a power supply that supplies a voltage to the resistor 15 via the electrode 16. Further, a photocurrent is input from the photodetector 14. Based on a photocurrent spectrum obtained from the photocurrent and the voltage supplied to the resistor 15, a characteristic (waveguide loss) of the optical circuit is evaluated (described later).

Light from a light source propagates through the optical fiber 21, is input to the optical input element 11 in the optical characteristic inspection circuit, and is split by the optical splitter circuit 12. One split light beam is input to the first optical circuit 13_1, and the other split light beam is input to the second optical circuit 13_2. Output light beams from the first optical circuit 13_1 and the second optical circuit 13_2 are input to the photodetector 14.

In the photodetector 14, the input light is converted into electricity, is output as a photocurrent, and is input to the control unit 31. Here, electrical output (photocurrent) from the photodetector 14 corresponds to the sum of intensities of the light beams transmitted through the first optical circuit 13_1 and the second optical circuit 13_2.

Operation of Optical Characteristic Inspection Circuit

Next, a basic operation of the optical characteristic inspection circuit 10 will be described. In the optical characteristic inspection circuit 10, a transmission characteristic of the optical splitter circuit 12 and a splitting ratio thereof change depending on a phase of input light.

In the input light having an arbitrary single wavelength and an arbitrary phase, one split light beam is transmitted through the first optical circuit 13_1 and then reaches the photodetector 14. The other light beam is transmitted through the second optical circuit 13_2 and then reaches the photodetector 14.

As a result, a photocurrent spectrum detected and output by the photodetector 14 is the sum of a current caused by the light transmitted through the first optical circuit 13_1 and a current caused by the light transmitted through the second optical circuit 13_2.

Here, the resistor (heater) 15 that generates heat by supply of electrical input from the outside and the electrode 16 connected to the resistor 15 via the electric wiring are disposed in the optical splitter circuit 12. When a voltage is applied to the resistor 15 via the electrode 16 and the electric wiring to cause the resistor 15 to generate heat, a refractive index changes due to the thermo-optic effect of the waveguide of the optical splitter circuit 12, thereby changing the phase of the input light.

The phase of the input light in the optical characteristic inspection circuit 10 is changed as described above, thereby changing the transmission characteristic of the optical splitter circuit 12 and the splitting ratio thereof. Based on a change in the photocurrent (photocurrent spectrum) caused by the change in the splitting ratio, optical characteristics (waveguide loss) of the first optical circuit 13_1 and the second optical circuit 13_2 are inspected. Details thereof will be described later.

### First Example

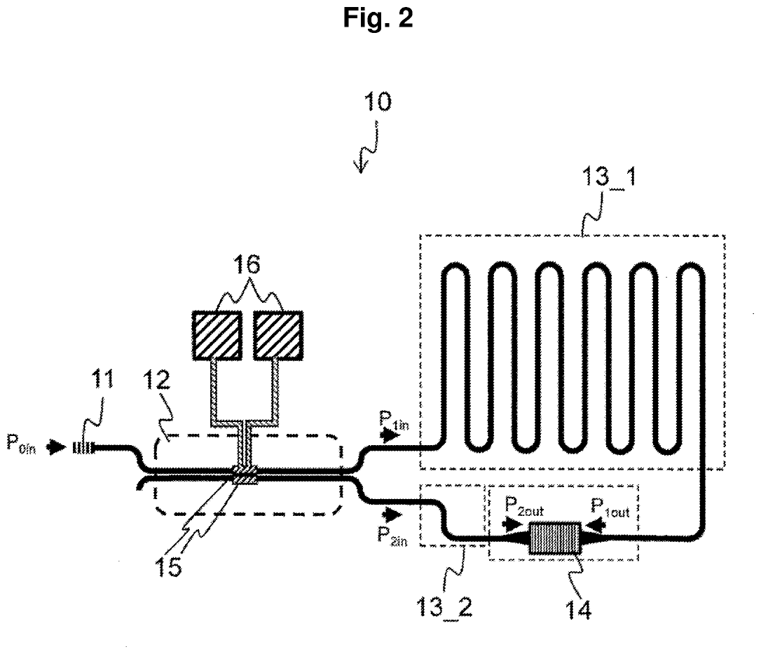

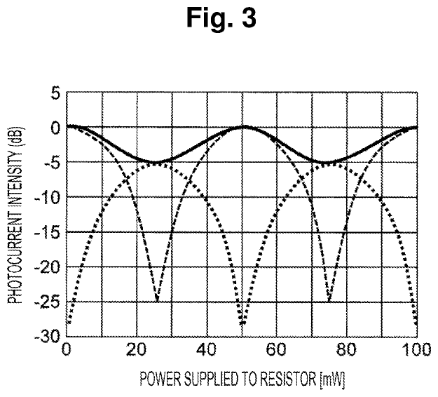

An optical characteristic inspection circuit and an optical characteristic inspection method according to a first example of the present invention will be described with reference to FIGS. 2 and 3.

Configuration of Optical Characteristic Inspection Circuit

The optical characteristic inspection circuit 10 according to the present example includes the grating coupler 11, the optical splitter circuit 12, the first optical circuit 13_1, the second optical circuit 13_2, and the photodetector 14. The grating coupler 11 may be another wafer surface optical input element.

In the optical characteristic inspection circuit 10, the resistors 15 are disposed in the waveguides of the optical splitter circuit 12. Further, the electrodes 16 are disposed in the resistors 15 via the electric wiring.

Operation of Optical Characteristic Inspection Circuit

Light having an arbitrary single wavelength and an arbitrary phase is input from the optical fiber to the grating coupler 11.

Then, the input light is input to the optical splitter circuit 12. The optical splitter circuit 12 is a directional coupler including two adjacent waveguides, two input ports, and two output ports. One input port is connected to one of the two waveguides and is connected to one output port. The one input port is connected to the grating coupler 11.

The other input port is connected to the other waveguide and is connected to the other output port. Here, the other input port is not substantially used, and thus the optical splitter circuit 12 only needs to have at least one input port.

A part of light input to the one input port of the optical splitter circuit 12 is transmitted through the one waveguide and is output from the one output port. At this time, the other part of the input light is coupled to and transmitted through the other waveguide in a region where the two waveguides are adjacent to each other and is output from the other output port.

In some cases, all the light input to the one input port of the optical splitter circuit 12 is transmitted through the one waveguide and is output from the one output port. Alternatively, all the input light may be coupled to and transmitted through the other waveguide in the region where the two waveguides are adjacent to each other and be output from the other output port.

The light output from the one output port is input to the first optical circuit 13_1. The light output from the other output port is input to the second optical circuit 13_2. The optical waveguides of the first optical circuit 13_1 and the second optical circuit 13_2 (hereinafter, the waveguides of the first optical circuit 13_1 and the second optical circuit 13_2 will be referred to as “optical waveguides”) have substantially equal quality and have different lengths. The quality corresponds to the waveguide loss per unit length and depends on a layer structure, a cross-sectional shape, and the like.

The light beams output from the first optical circuit 13_1 and the second optical circuit 13_2 are input to the photodetector 14. FIG. 2 illustrates an example where the output light beams from the first optical circuit 13_1 and the second optical circuit 13_2 are input to different end surfaces of the photodetector 14. However, the output light beams may be input to the same end surface of the photodetector 14.

In the photodetector 14, the input light is changed into electricity and is output as a photocurrent. Here, the photocurrent corresponds to the sum of intensities of the light beams transmitted through the first optical circuit 13_1 and the second optical circuit 13_2.

In the optical characteristic inspection circuit 10, the resistor 15 is disposed in each of the two adjacent waveguides in the optical splitter circuit 12. The resistors 15 generate heat when receiving application of a voltage via the electrodes 16 and the electric wiring. As a result, as temperatures of the waveguides change, the refractive index changes due to the thermo-optical effect of the waveguides. This makes it possible to change the phase of the input light. The change in the phase of the input light changes the transmission characteristics of the waveguides of the optical splitter circuit 12. Therefore, it is possible to change the splitting ratio of the light split and output from each waveguide.

The resistor 15 may be disposed in any one of the two waveguides. In a case where metal or the like serving as the resistor is disposed on a surface of the waveguide, light propagating through the waveguide is scattered by the metal or the like, thereby causing optical loss. In order to equalize an influence of the optical loss in both the waveguides, it is desirable to dispose resistors in both the waveguides.

For example, when a voltage is applied to the resistor 15 disposed in one of the two waveguides, it is possible to change the splitting ratio of output light, in other words, intensities of light beams input to the first optical circuit 13_1 and the second optical circuit 13_2. Alternatively, the voltage may be applied to the resistors 15 disposed in both of the two waveguides.

As described above, in the optical characteristic inspection circuit 10, the intensities of the light beams transmitted through the first optical circuit 13_1 and the second optical circuit 13_2 are changed by changing the voltage applied to the resistor 15. Therefore, the photocurrent in the photodetector 14 is changed. Based on the change in the photocurrent (photocurrent spectrum), it is possible to evaluate the waveguide loss of the optical waveguides of the optical circuit. Details thereof will be described below.

Optical Characteristic Inspection Method

FIG. 3 illustrates a schematic diagram of the photocurrent spectrum obtained in the photodetector 14. The photocurrent spectrum is obtained by changing the voltage applied to the resistor 15, that is, power supplied to the resistor and measuring the photocurrent.

In FIG. 3, a dotted line indicates a photocurrent contribution component of the first optical circuit 13_1, and a broken line indicates a photocurrent contribution component of the second optical circuit 13_2. A solid line indicates the photocurrent spectrum measured by the photodetector 14 and corresponds to the sum of the photocurrent contribution components of the first optical circuit 13_1 and the second optical circuit 13_2. Each amplitude of the photocurrent spectrum corresponds to the waveguide loss of the optical circuit.

In the optical characteristic inspection circuit 10, the first optical circuit 13_1 is longer than the second optical circuit 13_2, and thus the first optical circuit has larger optical loss. Therefore, the photocurrent contribution component of the first optical circuit 13_1 is smaller than the photocurrent contribution component of the second optical circuit 13_2.

Therefore, at a local minimal value in the photocurrent spectrum (solid line), the light intensity is minimal, that is, the optical loss is maximal. This corresponds to a case where all the input light is transmitted through the first optical circuit 13_1. In other words, the photocurrent contribution component of the first optical circuit 13_1 is 100%. As described above, the local minimal value in the photocurrent spectrum (solid line) is due to the waveguide loss of the first optical circuit 13_1.

Meanwhile, at a local maximal value in the photocurrent spectrum (solid line), the light intensity is maximal, that is, the optical loss is minimal. This corresponds to a case where all the input light is transmitted through the second optical circuit 13_2. In other words, the photocurrent contribution component of the second optical circuit 13_2 is 100%. As described above, the local maximal value in the photocurrent spectrum (solid line) is due to the waveguide loss of the second optical circuit 13_2.

Therefore, a difference (ΔS) between the local maximal value and the local minimal value of the photocurrent is due to a difference in waveguide loss caused by the difference in length (ΔL) between the first optical circuit 13_1 and the second optical circuit 13_2.

Therefore, it is possible to evaluate the waveguide loss per unit length by calculating ΔS/ΔL (dB/m) as an inspection result of the optical waveguides in the optical circuit.

In a case where the photocurrent spectrum has a plurality of local maximal values (or local minimal values), an average value of the plurality of local maximal values (or local minimal values) may be used to calculate ΔS/ΔL. Alternatively, one value may be selected and used from the plurality of local maximal values (or local minimal values). A maximum value or a minimum value may also be used.

Here, the common photodetector 14 is used in the optical characteristic inspection circuit 10. Therefore, even in a case where sensitivity varies in each manufactured photodetector, the entire photocurrent spectrum merely increases or decreases, and an amplitude thereof is not affected. Accordingly, it is similarly possible to evaluate the waveguide loss of the optical waveguides of the optical circuit formed on the substrate by acquiring and evaluating the photocurrent spectrum by using the optical characteristic inspection circuit including the optical circuits of different lengths.

The optical characteristic inspection circuit and the optical characteristic inspection method according to the present example do not need to sweep the wavelength of the input light. Therefore, even in a case where the optical input element having the wavelength dependence is used, it is possible to accurately evaluate the optical characteristics (waveguide loss) of the optical waveguides in on-wafer inspection.

Further, it is only necessary to align the optical fiber on the input side, and the photocurrent spectrum can be easily acquired after the alignment of the optical fiber. This makes it possible to simplify processes required for the inspection.

Furthermore, because the common photodetector is used in the optical characteristic inspection circuit, it is possible to suppress an influence of variations in characteristics of photodetectors.

As described above, it is possible to form the optical characteristic inspection device according to the first embodiment by using the optical characteristic inspection circuit according to the present example and to inspect the optical characteristics of the optical circuit.

### Second Example

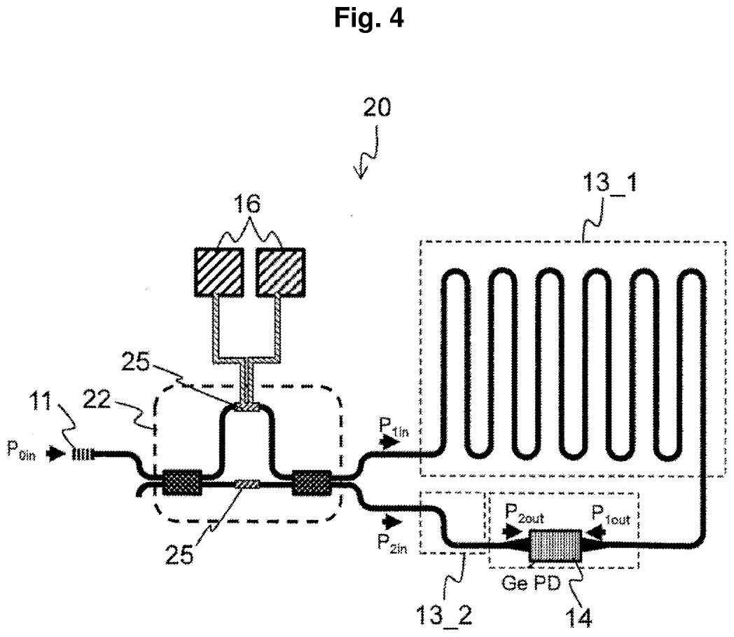

An optical characteristic inspection circuit according to a second example of the present invention will be described with reference to FIG. 4.

Configuration of Optical Characteristic Inspection Circuit

An optical characteristic inspection circuit 20 according to the present example includes the grating coupler 11, an optical splitter circuit 22, the first optical circuit 13_1, the second optical circuit 13_2, and the photodetector 14.

In the optical characteristic inspection circuit 20, resistors 25 are disposed in a waveguide of the optical splitter circuit 22. Further, the electrodes 16 are disposed in the resistor 25 via electric wiring.

In the optical characteristic inspection circuit 20, the optical splitter circuit 22 is a so-called asymmetric Mach-Zehnder interferometer including multimode interferometers (MMIs) at both input and output ends and two arm waveguides having different lengths.

Operation of Optical Characteristic Inspection Circuit

The asymmetric Mach-Zehnder interferometer optical splitter circuit 22 splits light, inputs the split light beams to the two arm waveguides, merges the light beams from the arm waveguides, then splits the light beams, and outputs the split light beams to both the first optical circuit 13_1 and the second optical circuit 13_2.

Here, a voltage is applied to at least one of the resistors 25 disposed in the two arm waveguides, thereby causing the resistor to generate heat. As a result, as a temperature of the arm waveguide changes, the refractive index changes due to the thermo-optical effect of the arm waveguide. This makes it possible to change a phase of input light. The change in the phase of the input light changes transmission characteristics of the arm waveguides. Therefore, it is possible to change the splitting ratio of output light.

In the optical characteristic inspection circuit 20, light from a light source is input to the grating coupler 11, is split by the optical splitter circuit 22, is transmitted through both the first optical circuit 13_1 and the second optical circuit 13_2, and is input to the photodetector 14, as in the first embodiment. The waveguide loss of the optical waveguides of the optical circuit is evaluated based on a photocurrent spectrum acquired by changing the voltage applied to the resistor 25.

The optical characteristic inspection circuit according to the present example can have effects similar to those of the first example.

The optical characteristic inspection device according to the first embodiment can be formed by using the optical characteristic inspection circuit according to the present example.

The characteristics of the optical circuit can be inspected by the optical characteristic inspection method according to the first example by using the optical characteristic inspection circuit according to the present example.

In the embodiment and examples of the present invention, both the directional coupler and the asymmetric Mach-Zehnder interferometer can be fabricated on a commercially available silicon-on-insulator substrate by using known lithography, thin film deposition, and dry etching techniques.

Further, in the embodiment and examples of the present invention, the photodetector can be made from a germanium photodiode or the like and can be fabricated on a commercially available silicon-on-insulator substrate by combining selective growth using an ultra-high vacuum chemical vapor deposition method or the like with lithography, thin film deposition, and dry etching.

The photodetector may also be made from an indium gallium arsenide photodiode or the like and can be fabricated by bonding a wafer or die including an indium phosphide thin film onto a commercially available silicon-on-insulator substrate by a wafer bonding technique, removing an unnecessary part of the substrate, and then combining lithography, crystal regrowth, and dry etching.

In the embodiment and examples of the present invention, an example of using a silicon optical circuit whose core material is silicon has been described. However, the present invention is not limited thereto. The core material only needs to have a refractive index larger than a refractive index of a clad material. For example, in a case where the clad material is a silicon oxide film, the core material may be a silicon oxide film, silicon oxynitride film, silicon nitride film, silicon carbide film, or the like having a high silicon content or may be a compound semiconductor such as gallium arsenide or indium phosphide. The clad material only needs to have a refractive index smaller than the refractive index of the core material. For example, in a case where the core material is silicon, the clad material may be a silicon oxide film, a silicon oxynitride film, or a silicon nitride film or may be an organic material such as epoxy resin or polyimide.

The embodiment of the present invention shows an example of a structure, dimensions, materials, and the like of each component in the configuration, manufacturing method, and the like of the optical characteristic inspection circuit. However, the present invention is not limited thereto. The optical characteristic inspection circuit is only required to exhibit its function and achieve effects.

### INDUSTRIAL APPLICABILITY

The present invention can be applied to an optical characteristic inspection device or the like used for inspecting an optical waveguide included in an optical device.

### REFERENCE SIGNS LIST

1 Optical characteristic inspection device
10 Optical characteristic inspection circuit
11 Optical input element
12 Optical splitter circuit
13_1 First optical circuit to be inspected (first optical circuit)
13_2 Second optical circuit to be inspected (second optical circuit)
14 Photodetector
15 Resistor
16 Electrode
21 Optical fiber
31 Control unit

1. An optical characteristic inspection circuit comprising, in order,
an optical input element,
an optical splitter circuit including a resistor,
a first optical circuit to be inspected connected to one output of the optical splitter circuit,
a second optical circuit to be inspected connected to another output of the optical splitter circuit, and
a photodetector configured to detect an intensity of light transmitted through the first optical circuit to be inspected and an intensity of light transmitted through the second optical circuit to be inspected.

2. The optical characteristic inspection circuit according to claim 1, wherein:
the optical splitter circuit includes two waveguides; and
the resistor is disposed in at least one of the two waveguides.

3. An optical characteristic inspection device comprising:
the optical characteristic inspection circuit according to claim 1; and
a control unit, wherein
the control unit acquires a photocurrent spectrum on the basis of a voltage supplied to the resistor and a photocurrent input from the photodetector.

4. The optical characteristic inspection device according to claim 3, wherein
the control unit calculates waveguide loss of the first optical circuit to be inspected and the second optical circuit to be inspected on the basis of the photocurrent spectrum.

5. An optical characteristic inspection method using the optical characteristic inspection circuit according to claim 1, the method comprising:
a step of changing a voltage to be supplied to the resistor;
a step of acquiring a photocurrent of light transmitted through the first optical circuit to be inspected and light transmitted through the second optical circuit to be inspected;
a step of acquiring a photocurrent spectrum on the basis of the voltage and the photocurrent; and
a step of calculating waveguide loss per unit length on the basis of a difference between a local maximal value and a local minimal value of the photocurrent spectrum and a difference between the first optical circuit to be inspected and the second optical circuit to be inspected.

6. An optical characteristic inspection device comprising:
the optical characteristic inspection circuit according to claim 2; and
a control unit, wherein
the control unit acquires a photocurrent spectrum on the basis of a voltage supplied to the resistor and a photocurrent input from the photodetector.

7. An optical characteristic inspection method using the optical characteristic inspection circuit according to claim 2, the method comprising:
a step of changing a voltage to be supplied to the resistor;
a step of acquiring a photocurrent of light transmitted through the first optical circuit to be inspected and light transmitted through the second optical circuit to be inspected;
a step of acquiring a photocurrent spectrum on the basis of the voltage and the photocurrent; and
a step of calculating waveguide loss per unit length on the basis of a difference between a local maximal value and a local minimal value of the photocurrent spectrum and a difference between the first optical circuit to be inspected and the second optical circuit to be inspected.
